(19) United States
(12) Patent Application Publication
(10) Pub. No.: US 2009/0184336 A1
(43) Pub. Date: Jul. 23, 2009

(54) SEMICONDUCTOR LIGHT EMITTING DEVICE AND MANUFACTURING METHOD THEREFOR

(75) Inventors: Takafumi Oka, Tokyo (JP); Shinji Abe, Tokyo (JP); Kazushige Kawasaki, Tokyo (JP); Hitoshi Sakuma, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/170,503

(22) Filed: Jul. 10, 2008

(30) Foreign Application Priority Data
Jan. 23, 2008 (JP) 2008-013131

(51) Int. Cl. H01L 33/00

(52) U.S. Cl. 257/99; 438/22; 257/E33.063

(57) ABSTRACT

A semiconductor light emitting device includes: a semiconductor layer; an insulating film on the semiconductor layer and having an opening; a multilayer adhesive layer on the insulating film; and a Pd electrode in contact with the semiconductor layer through the opening and in contact with the multilayer adhesive layer. The multilayer adhesive layer includes an Au layer at the top and an alloy of Au and Pd at the interface between the Au layer and the Pd electrode.

### BACKGROUND OF THE INVENTION

1. Field of the Invention

The present invention relates to a semiconductor light emitting device in which a Pd electrode is formed on the p-type contact layer, and also relates to a method for manufacturing such a semiconductor light emitting device.

2. Background Art

Semiconductor light emitting devices having a ridge structure are designed such that a voltage is applied to the p-type contact layer at the top of the ridge to supply power to the active layer (see, e.g., JP-A-2007-27181). An electrode is formed on the p-type contact layer to receive this voltage. The requirements of the electrode material include providing good ohmic characteristics and a low contact resistance with the contact layer (see, e.g., JP-A-2006-237476). Further, the electrode material should preferably not come off during the manufacturing process in order to ensure good yield and reliability of the semiconductor light emitting device. That is, the electrode material must have low resistance ohmic characteristics and the property of firmly adhering to the underlying layer without the possibility of peeling off (see, e.g., JP-A-2003-198065 and JP-A-2006-128622).

A problem with nitride semiconductor light emitting devices used as blue-violet LDs is that the use of Ni, etc. as the p-type electrode material prevents the electrode from having good ohmic characteristics and other desirable electrical characteristics, as is known in the art. To avoid this problem, it is common to use Pd as the p-type electrode material in nitride semiconductor light emitting devices of GaN, etc. Pd and Pd-based material are especially used to form a low resistance ohmic electrode in GaN devices (see, e.g., JP-A-2005-340625).

It is common for a p-type electrode of Pd to be formed to contact the underlying insulating film as well as the underlying p-contact layer. In such a case, an adhesive layer is additionally formed between the Pd electrode and the insulating film, since the Pd electrode has poor adhesion to the insulating film and hence may peel off. The above JP-A-2006-128622 discloses semiconductor light emitting devices including an adhesive layer made of a degenerate semiconductor such as ITO (indium tin oxide), or made of a platinum group metal or an oxide thereof.

It has been found, however, that the adhesive layers disclosed in this patent publication still cannot provide sufficient adhesion between the Pd electrode and the underlying insulating film, and hence a portion of the Pd electrode may peel off. On the other hand, there is a need to increase the output power and reduce the operating current of blue-violet LDs formed of a nitride semiconductor. That is, the Pd electrodes (or p-type electrodes) in these LDs must have a lower resistance and better ohmic characteristics than conventional Pd electrodes. It should be noted that the electrode configurations disclosed in the above patent publication cannot satisfy these requirements.

### SUMMARY OF THE INVENTION

The present invention has been devised to solve the above problems. It is, therefore, an object of the present invention to provide a semiconductor light emitting device in which the Pd electrode (or p-type electrode) is firmly adhered to the underlying insulating film without the possibility of coming off and has improved low resistance ohmic characteristics, which allows the device to deliver higher power and to operate at a lower current than prior laser devices of the same type. The present invention also provides a method for manufacturing such a semiconductor light emitting device.

According to one aspect of the present invention, a semiconductor light emitting device includes a semiconductor layer, an insulating film formed on said semiconductor layer and having an opening therein, a multilayer adhesive layer formed on said insulating film, and a Pd electrode formed in contact with said semiconductor layer through said opening and in contact with said multilayer adhesive layer. The multilayer adhesive layer includes an Au layer at the top. An alloy of Au and Pd is formed at the interface between said Au layer and said Pd electrode.

According to another aspect of the present invention, a method for manufacturing a semiconductor light emitting device includes the following steps. A wafer providing step of providing a wafer which includes a semiconductor layer having a ridge structure which includes a contact layer at the top. A resist forming step of forming a resist on said contact layer. An insulating film forming step of forming an insulating film on a surface of said wafer after said resist forming step. A multilayer adhesive layer forming step of forming a multilayer adhesive layer on said insulating film. A lift-off step of removing said resist after said multilayer adhesive layer forming step. A Pd electrode forming step of, after said lift-off step, forming a Pd electrode continuously covering said contact layer and said multilayer adhesive layer. A sintering heat treatment step of applying a sintering heat treatment to said wafer after said Pd electrode forming step. The multilayer adhesive layer includes an Au layer at the top and further includes a Ti layer or a Cr layer in contact with said insulating film. The application of said sintering heat treatment is such that an alloy of Au and Pd is formed at the interface between said Au layer and said Pd electrode.

Other and further objects, features and advantages of the invention will appear more fully from the following description.

### BRIEF DESCRIPTION OF THE DRAWINGS

FIG. 1 is a cross-sectional view of the semiconductor light emitting device of the embodiment;

FIG. 2 shows a wafer that includes an active layer and a p-type semiconductor layer formed on the active layer;

FIG. 3 is a cross-sectional view explaining the steps for exposure and development;

FIG. 4 is a cross-sectional view of the wafer after film-forming step;

FIG. 5 is a cross-sectional view explaining the step for Ti layer formation;

FIG. 6 is a cross-sectional view of the wafer after lift-off step;

FIG. 7 is a cross-sectional view explaining the resist formation;

FIG. 8 is a cross-sectional view of the wafer with the Pd layer;

FIG. 9 is a cross-sectional view of the wafer after lift-off step;

FIGS. 10 and 11 show an exemplary conventional device configuration;

FIG. 12 shows current paths other than straight current path;

FIG. 13 shows straight current path and roundabout current paths;

FIG. 14 is a cross-sectional view of light emitting device with basic construction;

FIG. 15-17 are cross-sectional views explaining other constructions within the scope of present invention;

FIG. 18 shows a wafer having a ridge portion, channel portions, and terrace portions;

FIG. 19 shows a resist formed wafer;

FIGS. 20 and 21 show a wafer with second insulating film, a Ti layer, and an Au layer;

FIG. 22 is a diagram explaining the film removal steps;

FIG. 23 is a diagram explaining resist formation step;

FIGS. 24 and 25 are explaining the Pd electrode formation;

FIG. 25 is a cross-sectional view explaining the lift-off of Pd electrode; and

FIGS. 26 and 27 show multilayer adhesive layer.

### DETAILED DESCRIPTION OF THE PREFERRED EMBODIMENT

### Embodiment

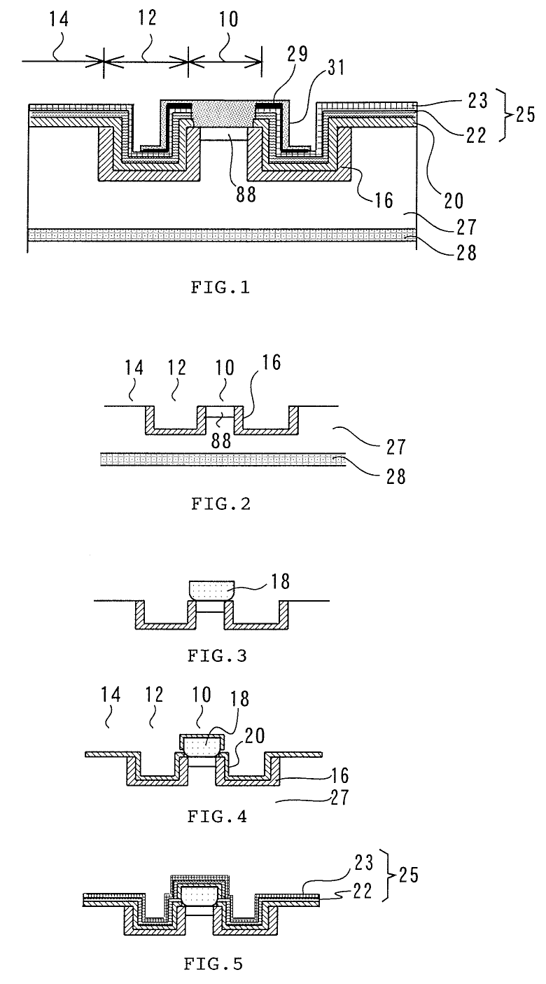

A embodiment of the present invention provides a semiconductor light emitting device in which the p-type electrode (or Pd electrode) is adapted not to peel off the underlying contact layer and the underlying insulating film and have improved low resistance ohmic characteristics. This embodiment also provides a method for manufacturing such a semiconductor light emitting device. FIG. 1 is a cross-sectional view of the semiconductor light emitting device of the present embodiment. Referring to FIG. 1, this semiconductor light emitting device includes an active layer 28 and a p-type semiconductor layer 27 formed on the active layer 28. The p-type semiconductor layer 27 includes a p-type guiding layer, a p-type cladding layer, and a p-type contact layer 88. According to the present embodiment, the p-type semiconductor layer 27 and other layers are formed of GaN-based material.

A Pd electrode 31 (described later) is formed on and electrically coupled to the p-type contact layer 88 of the p-type semiconductor layer 27. The p-type contact layer 88 is disposed at the top of a ridge portion 10, as shown in FIG. 1. The ridge portion 10 has a stripe-shaped current confinement structure as viewed in plan and is formed in the p-type semiconductor layer 27, which constitutes a semiconductor multilayer structure (or resonator structure).

Channel portions 12 approximately 10 μm wide are disposed adjacent the ridge portion 10. That is, these channel portions 12, formed in and from the p-type semiconductor layer 27, sandwich and define the ridge portion 10, as shown in FIG. 1. (Naturally, the bottom surfaces of the channel portions 12 are lower than the top surface of the ridge portion 10.) Further, a terrace portion 14 is disposed on the side of each channel portion 12 opposite to the ridge portion 10. (The top surfaces of these terrace portions 14 are higher than the bottom surfaces of the channel portions 12.) That is, the ridge portion 10 and each terrace portion 14 formed in and from the p-type semiconductor layer 27 sandwich and define a respective channel portion 12.

The semiconductor light emitting device of the present embodiment further includes a first insulating film 16 disposed to cover and contact the surfaces of the channel portions 12 formed in and from the p-type semiconductor layer 27. In the present embodiment, the first insulating film 16 is made of SiO₂. In other embodiments, however, it may be made of a material selected from the group consisting of SiN, SiON, TEOS (tetraethyl orthosilicate), ZrO₂, TiO₂, Ta₂O₅, Al₂O₃, Nb₂O₅, Hf₂O₅, and AlN.

A second insulating film 20 is disposed to cover the first insulating film 16 on the channel portions 12 and to cover the terrace portions 14 formed in and from the p-type semiconductor layer 27. In the present embodiment, the second insulating film 20 is made of SiO₂. In other embodiments, however, it may be made of a material selected from the group consisting of SiN, SiON, TEOS (tetraethyl orthosilicate), ZrO₂, TiO₂, Ta₂O₅, Al₂O₃, Nb₂O₅, Hf₂O₅, and AlN.

Further, a Ti layer 22 covers the surface of the second insulating film 20, and an Au layer 23 covers the surface of the Ti layer 22. In the present embodiment, the Ti layer 22 has a thickness of 30 nm and the Au layer 23 has a thickness of 40 nm. The Ti layer 22 and the Au layer 23 serve to improve the adhesion between the second insulating film 20 and the Pd electrode 31 (described later). The Ti layer 22 and the Au layer 23 are collectively referred to hereinafter as the “multilayer adhesive layer 25.” As shown in FIG. 1, the multilayer adhesive layer 25 is formed to cover the channel portions 12 and the terrace portions 14.

Further, the Pd electrode 31 covers the p-type contact layer 88 and partially covers the Au layer 23. The Pd electrode 31 is used to supply power to the p-type semiconductor layer 27. Thus, in the present embodiment, the Pd electrode 31 is formed in contact with the p-type contact layer 88 at the top of the ridge portion 10 and in contact with the Au layer 23 on the channel portions 12. (The Pd electrode 31 continuously extends over the p-type contact layer 88 and the Au layer 23.) It should be noted that the Pd electrode 31 does not completely cover the channel portions 12. It extends to approximately an intermediate point between the ridge portion 10 and each terrace portion 14, thus covering the ridge portion 10 and a portion of the bottom of each channel portion 12. An alloy, or ally portion, 29 of Pd and Au is formed at the interface between the Pd electrode 31 and the Au layer 23, as shown in FIG. 1.

This completes the description of the configuration of the semiconductor light emitting device of the present embodiment. A method for manufacturing the semiconductor light emitting device shown in FIG. 1 will now be described with reference to FIGS. 2 to 8.

Referring to FIG. 2, this method begins by providing a wafer that includes an active layer 28 and a p-type semiconductor layer 27 formed on the active layer 28. The p-type semiconductor layer 27 has a p-type contact layer 88 at the top. The wafer is then patterned and etched to form channel portions 12, a ridge portion 10, and terrace portions 14. The ridge portion 10 formed in and from the p-type semiconductor layer 27 has the remaining p-type contact layer 88 at the top. A first insulating film 16 is then formed on the channel portions 12, as shown in FIG. 2. In the present embodiment, the first insulating film 16 is made of SiO₂. It should be noted that the active layer 28 is omitted from FIGS. 3 to 8.

Next, a resist is applied over the wafer and exposed and developed to leave a resist 18 on the ridge portion 10, as shown in FIG. 3.

A second insulating film 20 is then formed on the wafer shown in FIG. 3. FIG. 4 is a cross-sectional view of the wafer after this film-forming step. The second insulating film 20 covers the resist 18 on the ridge portion 10 and the first insulating film 16 on the channel portions 12 and also covers the terrace portions 14 formed in and from the p-type semiconductor layer 27. In the present embodiment, the second insulating film 20 is made of SiO₂.

Referring now to FIG. 5, a Ti layer 22 is then formed to cover the second insulating film 20. In the present embodiment, the Ti layer 22 has a thickness of 30 nm. An Au layer 23 is then formed to cover the Ti layer 22. These layers are reliably formed by vapor deposition or sputtering. The Ti layer 22 and the Au layer 23 are collectively referred to hereinafter as the “multilayer adhesive layer 25.”

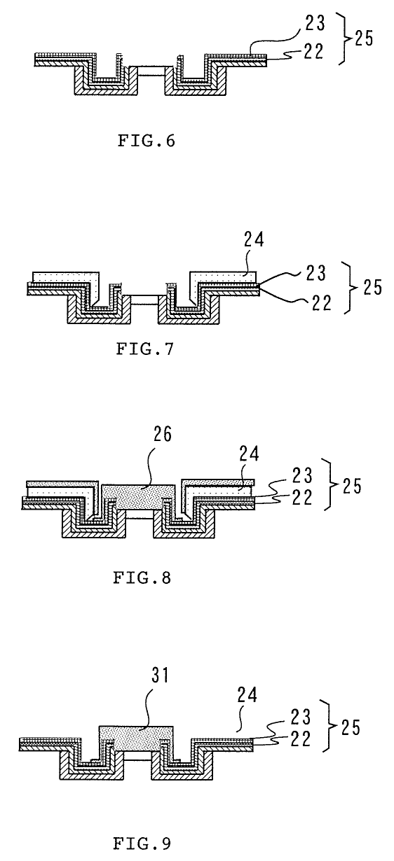

Next, the resist 18 and the overlying portions of the multilayer adhesive layer 25 and the second insulating film 20 are removed by lift-off, thereby exposing the p-type contact layer 88 at the top of the ridge portion 10. FIG. 6 is a cross-sectional view of the wafer after this lift-off step.

A resist 24 is then formed by photolithography to cover the terrace portions 14 and partially cover the channel portions 12, as shown in FIG. 7. More specifically, the resist 24 covers the top and sides of the terrace portions 14. (The side of each terrace portion 14 forms a sidewall of a respective channel portion 12.)

Next, a layer 26 of Pd is deposited onto the wafer shown in FIG. 7 by vapor deposition. FIG. 8 is a cross-sectional view of the wafer with the Pd layer 26 thereon. It should be noted that a Pd electrode 31 is formed from the Pd layer 26 later in the process. The Pd layer 26 is formed to cover and contact the p-type contact layer 88 at the top of the ridge portion 10, the multilayer adhesive layer on the sides of the ridge portion 10 (within the channel portions 12) and on portions of the bottoms of the channel portions 12, and the resist 24 on the top and sides of the terrace portions 14, as shown in FIG. 8. The Pd electrode contacts the resist 24 on the terrace portion.

The resist 24 and the overlying portion of the Pd layer 26 are then removed by lift-off. FIG. 9 is a cross-sectional view of the wafer after this lift-off step. The remaining portion of the Pd layer 26 on the wafer forms the Pd electrode 31. The Pd electrode 31 covers and contacts the p-type contact layer 88 at the top of the ridge portion 10 and the multilayer adhesive layer 25 on the sidewalls of the ridge portion 10 (within the channel portions 12) and on portions of the bottom surfaces of the channel portions 12, as shown in FIG. 9.

Next, the wafer shown in FIG. 9 is subjected to a sintering heat treatment at approximately 400-550° C. FIG. 1 shows the structure of the wafer after this sintering heat treatment step. The sintering heat treatment enhances the adhesion between the Pd electrode 31 and the p-type contact layer 88 at the top of the ridge portion 10 and forms an alloy portion 29 of Au and Pd between the Pd electrode 31 and the multilayer adhesive layer 25 on the channel portions 12.

The semiconductor light emitting device of the present invention is characterized in that it includes the alloy portion 29 formed at the interface between the Pd electrode 31 and the Au layer 23. The effect of this alloy portion 29 will now be described. Increasing the output power and reducing the current consumption of a laser requires that the p-type electrode in contact with the underlying p-type semiconductor layer (or contact layer) be a low resistance ohmic electrode. For example, the p-type electrode of blue-violet lasers of a GaN-based material is preferably a low resistance ohmic electrode made of Pd. However, it is difficult, due to process limitation, to form this Pd electrode in such a way that the electrode is only in contact with the underlying p-type semiconductor layer (or contact layer). That is, it happens that the formed Pd electrode is also in contact with the underlying insulating film. It has been found, however, that in such a case the Pd electrode has poor adhesion to the insulating film and peels off. This peeling of the Pd electrode tends to occur after the sintering heat treatment, although it may occur any time after the formation of the Pd electrode.

The semiconductor light emitting device of the present embodiment is designed such that the Pd electrode (or p-type electrode) does not peel off the underlying contact layer and the underlying insulating film and has low resistance ohmic characteristics, which allows the device to deliver higher power and to operate with a lower current consumption than prior devices of the same type. The method of the present embodiment as described above allows the manufacture of such a semiconductor light emitting device. Specifically, in the semiconductor light emitting device of the present embodiment, the alloy portion 29 is formed at the interface between the Pd electrode 31 and the Au layer 23 to improve the adhesion between them as shown in FIG. 1. Furthermore, the Ti layer 22 of the multilayer adhesive layer 25 covers and contacts the second insulating film 20. The Ti layer 22 has good adhesion to the second insulating film 20.

According to the present embodiment, a sintering heat treatment is performed in such a way as to enhance the adhesion between the Pd electrode 31 and the p-type contact layer 88 while at the same time forming the alloy portion 29 at the interface between the Pd electrode 31 and the Au layer 23. This means that the method of the present embodiment does not require an additional process step to form the alloy portion 29.

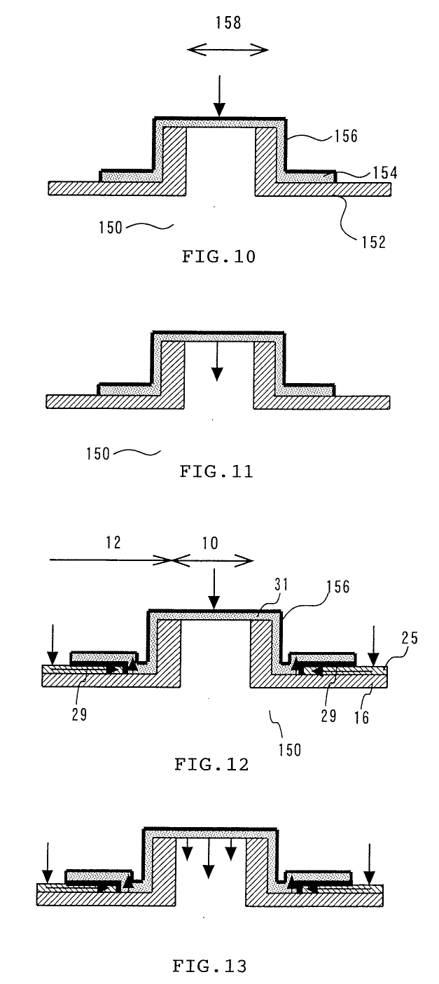

It should be noted that a pad electrode may be formed over the surface of the wafer after the above sintering heat treatment. This pad electrode is used to supply power to the p-type semiconductor layer (or contact layer). FIG. 10 shows an exemplary conventional device configuration including a pad electrode (not shown). Referring now to FIG. 10, a problem with this configuration is that the Pd electrode 154 formed over the ridge portion 158 of a p-type semiconductor layer 150 may have an unwanted electrode surface oxide layer 156 thereon. Specifically, this electrode surface oxide layer 156 is formed, for example, when the sintering heat treatment is performed in an oxygen atmosphere. This may result in an increase in the device resistance, since the electrode surface oxide layer 156 is located between the Pd electrode 154 and the pad electrode. That is, in the case of this device, not all of the current from the pad electrode may pass through the p-type semiconductor layer 150 due to the presence of the electrode surface oxide layer 156, as schematically indicated by the thick and thin arrows in FIGS. 10 and 11, respectively.

On the other hand, the semiconductor light emitting device of the present embodiment is substantially immune to this problem, since it includes, in addition to the above straight current path via the electrode surface oxide layer 156, other current paths from the pad electrode above the ridge portion 10 to the p-type semiconductor layer 150 via the multilayer adhesive layer 25 and the alloy portion 29 (i.e., not via the electrode surface oxide layer 156), as shown in FIG. 12. That is, all of these paths allow a current to pass from the pad electrode to the Pd electrode 31 and to the p-type semiconductor layer 150, resulting in increased power supply to the semiconductor light emitting device (or the active layer). In FIG. 13, the arrows indicate the currents flowing through the straight current path (via the electrode surface oxide layer 156) and the roundabout current paths (along both sides of the ridge portion 10).

The configuration of the semiconductor light emitting device of the present embodiment, in which the roundabout current paths along both sides of the ridge portion 10 are provided, allows the device to have a lower device resistance, as compared not only to the configuration shown in FIG. 10 in which no adhesive layer is provided, but also to those in which the multilayer adhesive layer is partially made of dielectric material or no alloy is formed at the interface between the Pd electrode and the multilayer adhesive layer.

It should be noted that the roundabout current paths along both sides of the ridge portion 10 have the effect of increasing the power supply to the active layer even when the Pd electrode has substantially no electrode surface oxide layer formed thereon. That is, this current path configuration of the present embodiment allows the device resistance to be reduced even when the Pd electrode has no electrode surface oxide layer thereon, resulting in an increase in the output power and a reduction in the current consumption of the semiconductor light emitting device.

It should be noted that the end face portions or even other portions of a semiconductor light emitting device may heat up during its operation. If the temperature of the semiconductor light emitting device exceeds an allowable value, the characteristics and reliability of the device may degrade. However, the semiconductor light emitting device of the present embodiment is less likely to suffer such a problem than prior devices, since it includes a multilayer adhesive layer made of a metal and hence has higher heat dissipation capability.

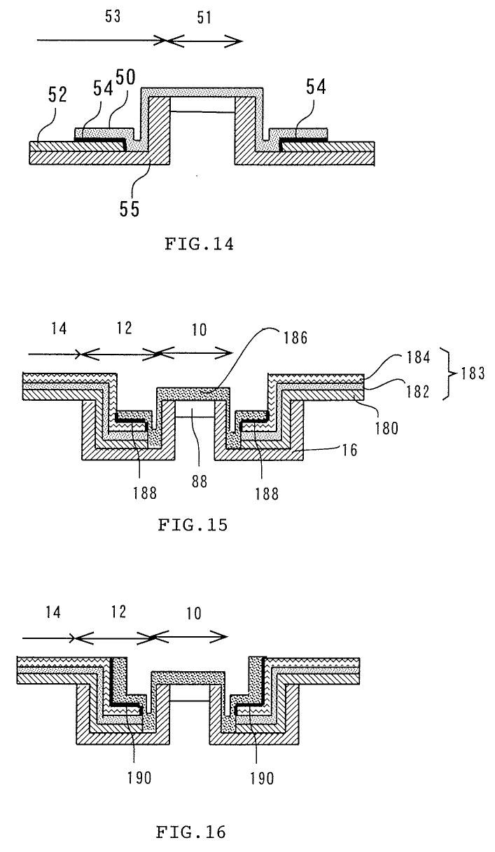

Although the semiconductor light emitting device of the present embodiment has been described as including terrace portions, it is to be understood that the device may include no terrace portions. The present embodiment requires only that the semiconductor light emitting device have a basic construction such as that shown in FIG. 14. The construction shown in FIG. 14 includes a ridge portion 51 and a non-ridge portion 53, and an alloy portion 54 is formed at the interface between the Pd electrode 50 and the multilayer adhesive layer 52. Reference numeral 55 denotes an insulating film.

Although the semiconductor light emitting device of the present embodiment has been described as including a multilayer adhesive layer that covers the second insulating film on the entire surfaces of the channel portions, it is to be understood that multilayer adhesive layers having different configurations may be substituted therefor. For example, the semiconductor light emitting device may have a construction such as that shown in FIG. 15. Specifically, the construction of FIG. 15 is such that: the second insulating film 180 covers the terrace portions and covers the first insulating film 16 on only portions of the surfaces of the channel portions; the Pd electrode 186 extends to cover and contact the first insulating film 16 on the other portions of the surfaces of the channel portions; the Pd electrode 186 further extends to cover and contact the Au layer 184 of the multilayer adhesive layer 183; and an alloy portion 188 is formed at the interface between the Pd electrode 186 and the Au layer 184.

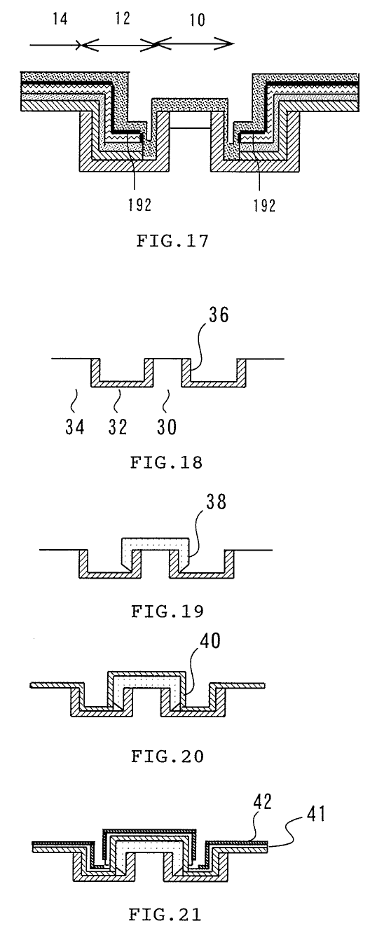

In this case it may happen that the Pd electrode 186 does not have sufficient adhesion to the first insulating film 16. However, the alloy portion 188 may compensate for this by firmly bonding the Pd electrode and the Au layer together. That is, this configuration may still retain the advantages of the present invention. However, since as shown in FIG. 15 the interface (and hence the alloy portion 188) between the Pd electrode and the Au layer extend across only relatively small portions of the surfaces of the channel portions, the adhesion between the Pd electrode and the Au layer may not be sufficient. In such a case, the area of the interface between the Pd electrode and the Au layer may be increased, as shown in FIGS. 16 and 17, to increase the area of the alloy portion formed at the interface. This enhances the adhesion between the Pd electrode and the Au layer and thereby prevents the Pd electrode from coming off the Au layer. Reference numeral 190 in FIG. 16 and reference numeral 192 in FIG. 17 denote alloy portions.

Incidentally, the semiconductor light emitting devices shown in FIGS. 15, 16, and 17 are easier to manufacture than that shown in FIG. 1. That is, the manufacture of the semiconductor light emitting device shown in FIG. 1 requires that a resist be formed to cover only the top surface of the ridge, as shown in FIG. 3. However, it is difficult, due to the limited capability of the manufacturing equipment, to ensure that all such semiconductor light emitting devices manufactured meet this requirement. To overcome this problem, the resist 38 shown in FIG. 19 may be formed instead of the resist 18 shown in FIG. 3. There will now be briefly described, with reference to FIGS. 18 to 25, a method for manufacturing a semiconductor light emitting device which includes forming the resist 38.

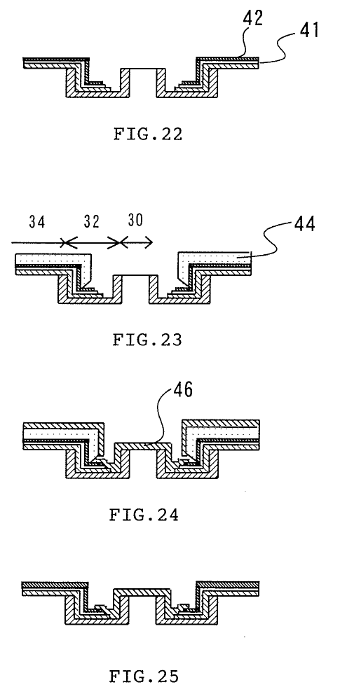

Referring to FIG. 18, this method begins by providing a wafer having formed therein a ridge portion 30, channel portions 32, and terrace portions 34. A first insulating film is then formed on the channel portions 32, as shown in FIG. 18. Next, a resist 38 is formed to cover the ridge portion 30, as described above (see FIG. 19). A second insulating film 40, a Ti layer 41, and an Au layer 42 are then successively formed, as shown in FIGS. 20 and 21. The resist 38 and the overlying portions of the second insulating film 40, the Ti layer 41, and the Au layer 42 are removed by lift-off, as shown in FIG. 22. Then, a resist 44 is formed on the terrace portions 34 and portions of channel portions 32, as shown in FIG. 23. A Pd electrode 46 is then formed, and the resist 44 and the overlying portion of the Pd electrode 46 are removed by lift-off, as shown in FIGS. 24 and 25. The wafer shown in FIG. 25 is then subjected to a sintering heat treatment, thereby producing a semiconductor light emitting device as shown in FIG. 15.

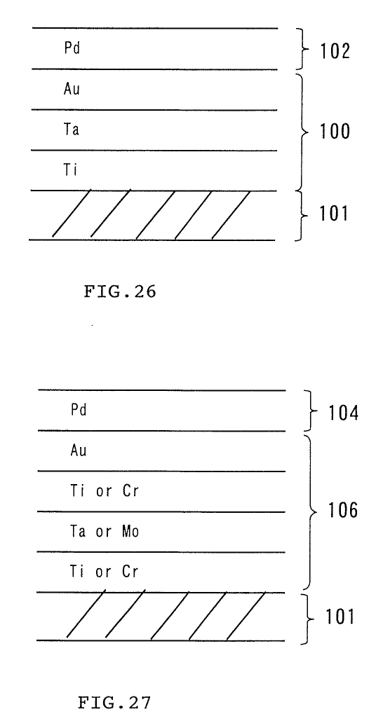

Although the semiconductor light emitting device of the present embodiment has been described as including a multilayer adhesive layer that includes a Ti layer and an Au layer formed on the Ti layer, it is to be understood that multilayer adhesive layers having different structures may be substituted therefor. For example, the semiconductor light emitting device may include the multilayer adhesive layer 100 shown in FIG. 26. Referring to FIG. 26, the multilayer adhesive layer 100, which is sandwiched between the second insulating film 101 and the Pd electrode 102, includes a Ti layer, a Ta layer, and an Au layer formed on top of one another on the second insulating film 101 in that order.

In the case of the multilayer adhesive layer in which the Au layer is formed on the Ti layer, Ti may diffuse to the alloy portion between the Au layer and the Pd electrode and then may oxidize into an oxide, which is not desirable since it may increase the resistance of the semiconductor light emitting device. The multilayer adhesive layer 100 shown in FIG. 26 does not present such a problem, since the Ta layer formed between the Ti layer and the Au layer prevents the diffusion of Ti into the Au layer (and hence the alloy portion), resulting in a reduction in the device resistance.

Further, the semiconductor light emitting device of the present embodiment may include one of the two multilayer adhesive layers shown in FIG. 27, instead of the multilayer adhesive layer 25. Referring to FIG. 27, the first multilayer adhesive layer, which is sandwiched between the second insulating film 101 and the Pd electrode 104, includes a Ti layer, a Ta layer, a Ti layer, and an Au layer formed on top of one another on the second insulating film 101 in that order. These layers can be mutually and firmly bonded together, since the Ti layers are located between the Ta layer and the second insulating film 101 and between the Ta layer and the Au layer. On the other hand, the second multilayer adhesive layer, which is sandwiched between the second insulating film 101 and the Pd electrode 104, includes a Cr layer, an Mo layer, a Cr layer, and an Au layer formed on top of one another on the second insulating film 101 in that order. These layers can also be mutually and firmly bonded together, since the Cr layers are located between the Mo layer and the second insulating film 101 and between the Mo layer and the Au layer.

It should be noted that the present embodiment does not require that the layers in the multilayer adhesive layer be of any particular thickness. Therefore, the thickness of each layer may be determined by the adhesion strength required.

Further, the Pd electrode may be made up of only a single layer of Pd, or may have a multilayer structure that includes a first layer of Pd and a layer(s) of a different material(s) formed on the first layer, with the first layer being in contact with the p-type contact layer. For example, the Pd electrode may have a two layer structure of Pd/Ta (i.e., Ta over Pd), a three layer structure of Pd/Ta/Pd (i.e., Pd over Ta over Pd), or a four or more layer structure (made up of a three layer structure of Pd/Ta/Pd with a layer(s) of a suitable material(s) formed thereon). It has been found from experimentation that a two layer structure of Pd/Ta has a lower contact resistance than a single layer of Pd. More specifically, when used in the configuration shown in FIG. 1, the contact resistivity of the two layer structure of Pd/Ta to the underlying layer was one to two orders of magnitude lower than that of the single Pd layer. It has also been found that the top Pd layer of a three layer structure of Pd/Ta/Pd prevents Ta oxidation.

It will be appreciated that various modifications and alterations may be made to the semiconductor light emitting device and the manufacturing method therefor of the present embodiment without departing from the spirit and scope of the present invention. That is, the present invention encompasses any semiconductor light emitting device having the following basic configuration. A multilayer adhesive layer made up of one or more metal layers is formed between the Pd electrode (p-type electrode) and the underlying insulating film, and an alloy portion is formed at the interface between the Pd electrode and the multilayer adhesive layer to enhance the adhesion between the Pd electrode and the underlying p-type semiconductor layer and the underlying insulating film as well as to improve the electrical characteristics of the device. Therefore, although the semiconductor light emitting device of the present embodiment has been described as including a GaN semiconductor layer, the present invention is not limited to this particular material system and can be applied to various material systems.

The entire disclosure of a Japanese Patent Application No. 2008-013131, filed on Jan. 23, 2008 including specification, claims, drawings and summary, on which the Convention priority of the present application is based, are incorporated herein by reference in its entirety.

Thus, the present invention provides a semiconductor light emitting device in which the Pd electrode (or p-type electrode) is adapted not to come off the underlying contact layer and the underlying insulating film and has improved low resistance ohmic characteristics. Further, the present invention also provides a method for manufacturing such a semiconductor light emitting device.

1. A semiconductor light emitting device comprising:
a semiconductor layer;
an insulating film on said semiconductor layer said insulating film having an opening;
a multilayer adhesive layer including a plurality of layers and on said insulating film; and
a Pd electrode in contact with said semiconductor layer through said opening and in contact with said multilayer adhesive layer, wherein
said multilayer adhesive layer includes an Au layer as said layer of said multilayer adhesive layer most distant from said insulating film and
an alloy of Au and Pd is located at the interface between said Au layer and said Pd electrode.

2. The semiconductor light emitting device as claimed in claim 1, wherein said multilayer adhesive layer further includes one of a Ti layer and a Cr layer in contact with said insulating film.

3. The semiconductor light emitting device as claimed in claim 2, wherein said multilayer adhesive layer further includes a Ta layer between said Au layer and said Ti layer or said Cr layer.

4. The semiconductor light emitting device as claimed in claim 1, wherein:
said multilayer adhesive layer further includes a first Ti or Cr layer, a Ta or Mo layer, and a second Ti or Cr layer; and
said first Ti or Cr layer, said Ta or Mo layer, said second Ti or Cr layer, and said Au layer are stacked on one another, in that order.

5. The semiconductor light emitting device as claimed in claim 1, wherein:
said semiconductor layer has a ridge structure which includes a p-type contact layer;
said opening exposes said ridge structure; and
said Pd electrode is in contact with said p-type contact layer through said opening.

6. The semiconductor light emitting device as claimed in claim 1, wherein:
said semiconductor layer includes a ridge structure, a channel portion, and a terrace portion, said channel portion being adjacent to and lower than said ridge structure, and said terrace portion being adjacent to and higher than said channel portion; and
said multilayer adhesive layer covers said terrace portion and said channel portion.

7. The semiconductor light emitting device as claimed in claim 1, wherein said Pd electrode has at least a two layer structure including a first Pd layer and a Ta layer on said Pd layer or including a Pd layer, a Ta layer, and a second Pd layer stacked on one another, in that order.

8. A method for manufacturing a semiconductor light emitting device, the method comprising: providing step f providing a wafer which includes a semiconductor layer having a ridge structure, said ridge structure including a contact layer as the part of said ridge structure most distant from said wafer forming a resist on said contact layer; forming an insulating film on a surface of said wafer after forming said resist; forming a multilayer adhesive layer, including a plurality of layers, forming on said insulating film; removing said resist after forming said multilayer adhesive layer; after removing said resist, forming a Pd electrode continuously covering said contact layer and said multilayer adhesive layer; and sintering, in a heat treatment after forming said Pd electrode; wherein
said multilayer adhesive layer includes an Au layer as said layer of said multilayer adhesive film most distant from said wafer and a Ti layer or a Cr layer in contact with said insulating film, and in sintering, forming an alloy of Au and Pd at the interface between said Au layer and said Pd electrode.

9. The method as claimed in claim 8, wherein said Pd electrode has at least a two layer structure including a Pd layer and a Ta layer on said Pd layer or including a first Pd layer, a Ta layer, and a second Pd layer stacked on one another, in that order.
